(19) United States
(12) Patent Application Publication
(10) Pub. No.: US 2006/0292885 A1
(43) Pub. Date: Dec. 28, 2006

(54) Layout modification to eliminate line bending caused by line material shrinkage

(75) Inventors: Vladimir Alexeevich Ukraintsev, Allen, TX (US); Mark E. Mason, Dallas, TX (US); James Walter Blatchford, Richardson, TX (US); Brian Ashley Smith, Plano, TX (US); Brian Edward Hornung, Richardson, TX (US); Dirk Noel Anderson, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/165,232

(22) Filed: Jun. 24, 2005

(51) Int. Cl. H01L 23/58; H01L 21/302

(52) U.S. Cl. 438/725; 257/632

(57) ABSTRACT

A semiconductor device and a method for fabricating a semiconductor device with reduced line bending is provided. The method can include forming a first layer and depositing a photoresist layer on the first layer. The photoresist layer can be patterned, such that the patterning comprises at least one support feature disposed adjacent to an outside of a corner feature.

### DESCRIPTION OF THE INVENTION

1. Field of the Invention

The present invention relates to etching processes during semiconductor device fabrication. More particularly, the present invention relates methods for reducing the effects of etch-related photoresist shrinkage during semiconductor device fabrication.

2. Background of the Invention

Lithographic projection apparatus (tools) can be used, for example, in the manufacture of integrated circuits (ICs). When using the various tools, a mask can be used that includes a circuit pattern corresponding to an individual layer of the IC, and this pattern can be imaged onto a target portion (e.g., comprising one or more dies) on a substrate, such as a silicon or other wafer comprising a semiconductor, that has been coated with a layer of radiation-sensitive material, such as a photoresist. The photoresist is selectively exposed to radiation, such as ultraviolet light, and then developed to form a patterned resist. The patterned resist should ideally respond to an exposing radiation such that the mask image is replicated in the resist. The patterned resist should also ideally protect the underlying material during subsequent processing steps, such as etching.

As semiconductor devices have continued to shrink in size, smaller wavelength optical lithography (“photolithography”) techniques have been developed. For example, 193 nm technology (technology using a radiation source having a wavelength of 193 nm to develop the photoresist) is being used to extend optical lithography to the dimensions required for the manufacture of 1 gigabyte DRAM and advanced CMOS microprocessors with 140-180 nm minimum feature sizes. Moreover, work is currently underway to develop the next generation of photolithography techniques that use 157 nm technology.

While 193 nm technology allows the resist to be patterned with smaller structures, problems arise because the resist suffers from shrinkage when exposed to wet or dry etching. FIG. 1A shows a portion of a mask image 100 that includes a corner feature 150. Fabrication of the corner structure is accomplished by patterning a photoresist to replicate corner feature 150. FIG. 1B shows a cross sectional view of a photoresist 151, patterned to replicate corner feature 150, on a layer 110. When layer 110 is etched to form a corner structure 111, line bending can result due to photoresist shrinkage. Referring again to FIG. 1A, resist shrinkage pulls corners inward forcing lines near corners to bend. The force is depicted by arrows 1, 2, and 3 in FIG. 1A. As shown in FIG. 1C, photoresist shrinkage exposes one side of corner structure 111 to etching agents. The line bending can lead to silicon (“poly”) line damage and/or erosion and, ultimately, result in device failure and yield loss.

Thus, there is a need to overcome these and other problems of the prior art and to provide a method to reduce the effects of photoresist shrinkage during etching.

### SUMMARY OF THE INVENTION

According to various embodiments, the present teachings include a method for fabricating a semiconductor device with reduced line bending. The method can include forming a first layer and depositing a photoresist layer on the first layer. The photoresist layer can be patterned, wherein the patterning comprises at least one support feature disposed adjacent to an outside of a corner feature.

According to various other embodiments, the present teachings include a method for forming a semiconductor device having reduced line bending. The method can include forming a first layer and forming a patterned mask layer on the first layer, wherein the patterned mask layer has a mask pattern comprising at least one support feature disposed at an outside of a corner feature. The method can further include etching the first layer to replicate the mask pattern in the first layer.

According to still further various embodiments, the present teachings include a semiconductor device including a first layer and a patterned mask layer on the first layer. The patterned mask layer can define a corner structure and define at least one support structure disposed adjacent to an outside of the corner structure.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1A depicts an exemplary portion of a mask image including a corner feature.

FIG. 1B depicts an exemplary patterned photoresist used to fabricate a corner feature.

FIG. 1C depicts line bending of a corner structure fabricated by conventional methods.

FIG. 2A depicts an exemplary portion of a mask image that includes a corner feature in accordance with the present teachings.

FIG. 2B depicts an exemplary patterned photoresist including a support feature used to fabricate a corner feature in accordance with the present teachings.

FIG. 2C depicts an exemplary corner structure fabricated using support features to reduce line bending in accordance with the present teachings.

FIG. 3 depicts another exemplary support feature.

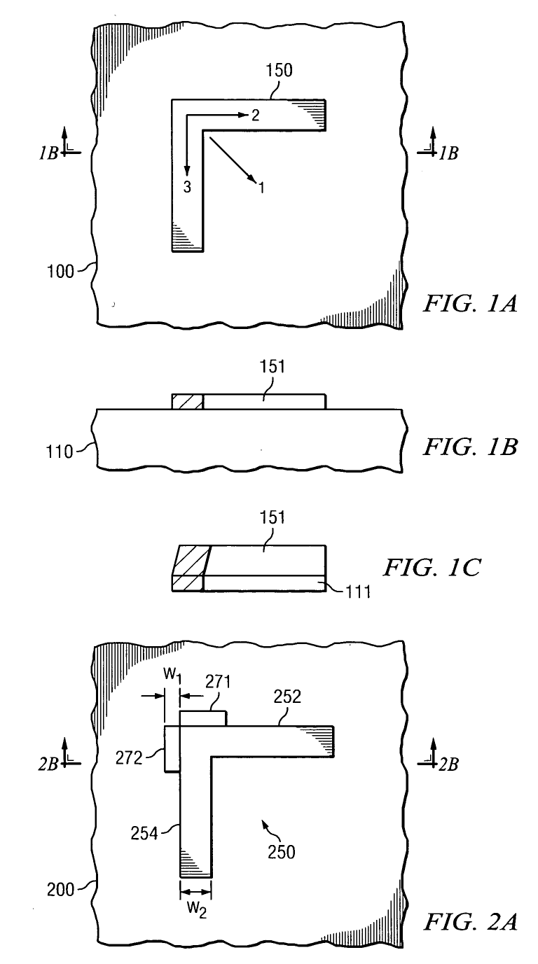

### DESCRIPTION OF THE EMBODIMENTS

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, not to be taken in a limited sense.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

The term mask, as used herein, can be broadly interpreted as referring to generic pattern means that can be used to endow an incoming beam with a patterned cross-section, corresponding to a target pattern that is to be created in a target portion of the substrate, including, but not limited to photoresists.

As used herein and unless otherwise specified, the term “feature” refers to a pattern(s) defined by a mask. For example, a gate structure can be defined in a mask image by a gate feature.

As used herein and unless otherwise specified, the term “structure” refers to patterns formed in a layer underlying the patterned mask. For example, a gate structure can be a gate formed by etching a layer, such as a polysilicon layer, underlying the patterned resist.

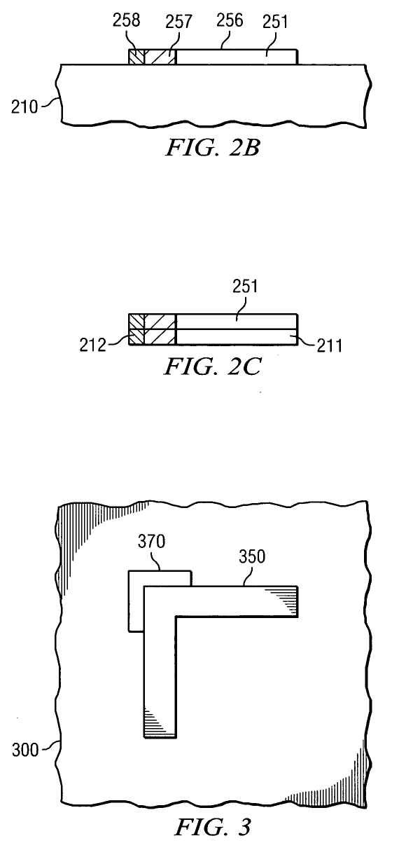

FIGS. 2A through 3 depict exemplary mask images including support features, semiconductor structures including support structures, and methods for fabricating the exemplary features and structures. The support features can be included in the layout and/or mask image, and formed by patterning a photoresist to position the support features adjacent to an outside of a corner feature. During etching, the support feature can compensate for an inward force on the corner features and reduce line bending. An exemplary method for forming a support feature will be describe below with reference to patterning and etching a polysilicon corner structure, such as, for example, a horizontally oriented field polysilicon structure connected to a vertically oriented field polysilicon structure. One of skill in the art will understand that the exemplary method is not limited to etching corner features in polysilicon and can be used to reduce line bending in any semiconductor process that uses a photoresistive material as a mask for etching.

Referring to the top view of FIG. 2A, a portion of a mask image 200 is shown. The portion of the mask image includes a corner feature 250 comprising a first portion 254 that defines, for example, a vertically oriented field polysilicon feature, and a second portion 252 that defines, for example, a horizontally oriented field polysilicon feature. To reduce line bending during etching, one or more support features 271 and 272 can be defined. One or more support features 271 and 272 can be, for example, positioned at an outside of corner feature 250. In various embodiments, one or more support features 271 and 272 can have a width w₁ equal to or greater than a width w₂ of gate structure 254.

Fabrication of corner feature 250 is shown in FIG. 2B. A photoresist layer can be formed on a layer 210. Layer 210 can be formed of any material used in semiconductor device manufacturing in which a pattern can be formed in by etching. Examples of materials of layer 210 include, but are not limited to metals, such as copper and aluminum, dielectrics, such as oxides and nitrides, and semiconductors, such as crystalline silicon, polysilicon and amorphous silicon. The photoresist can be formed of any material used in lithography as a radiation sensitive mask. Photoresists for 193 nm optical lithography technology can include, for example, JSR AR1395J, JSR AR237, and TOK TARF6071. The photoresist layer can be patterned to form a mask 251 that replicates corner feature 250. For example, mask 251 can include a first section 256 that corresponds to first portion 254 of corner feature 250, a second section 257 that corresponds to a second portion 252 of corner feature 250, and a third section 258 that corresponds to support feature 272. A fourth section can be included (not shown) that correspond to support feature 271.

Mask 251 can be then used to replicate the pattern of mask 251 in layer 210. Referring to FIG. 2C, a corner structure 211 can be formed by etching layer 210 with support features 271 and 272 disposed to oppose the forces resulting from etching. Etching can be by conventional methods known to one of ordinary skill in the art. The resultant structure can include corner structure 250, having reduced line bending, and corresponding to corner feature 210 in layout 210. The resultant structure further includes support structure 212 corresponding to support feature 272 in layer 210 and a support structure (not shown) corresponding to support feature 271.

According to various embodiments, support features can be used to reduce line bending during formation of any corner structure having a having an angle of less than 180°. For example, corner structures having angles of 90° or 135° can be formed using a patterned photoresist that includes support features. The support features can be positioned in the patterned photoresist at an outside of the comer features that define the corner structure.

While an exemplary embodiment has been described with reference to a gate poly-Si etch, one of ordinary skill in the art will understand that other embodiments are envisioned including, but not limited to, a shallow-trench isolation etch and an interconnect trench etch.

One of ordinary skill in the art will understand that other geometries can be used as support features to define support structures. For example, FIG. 3 depicts a portion of a layout 300 including a corner feature 350 and a support feature 370.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

As used herein, the term “one or more of” with respect to a listing of items such as, for example, A and B, means A alone, B alone, or A and B.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for fabricating a semiconductor device with reduced line bending compromising:
forming a first layer;
depositing a photoresist layer on the first layer; and
patterning the photoresist layer, wherein the patterning comprising at least one support feature disposed adjacent to an outside of a corner feature.

2. The method of claim 1, wherein the at least one support feature has a width equal to or greater than the line width of the corner feature.

3. The method of claim 1, further comprising etching the first layer to replicate the mask pattern in the first layer.

4. The method of claim 3, wherein the step of etching comprises dry etching or wet etching.

5. The method of claim 3, wherein the step of etching comprises a plasma etch.

6. The method of claim 1, wherein patterning the photoresist layer comprises using one of 193 nm lithography and 157 nm lithography.

7. The method of claim 1, wherein the at least one support feature comprises a first support feature disposed adjacent to a first side of the outside of the corner feature and a second support feature disposed adjacent to a second side of the outside of the corner feature.

8. The method of claim 1 wherein the at least one support feature is disposed at a location that is opposite to a direction of a force causing line bending.

10. A semiconductor device having reduced line bending formed by the steps comprising:
forming a first layer;
forming a patterned mask layer on the first layer, wherein the patterned mask layer has a mask pattern comprising at least one support feature disposed at an outside of a corner feature; and
etching the first layer to replicate the mask pattern in the first layer.

11. The semiconductor device of claim 10, wherein the at least one support feature has a width equal to or greater than the line width of the corner feature.

12. The semiconductor device of claim 10, wherein etching the first layer comprises etching by one of a dry etch or a wet etch.

13. The semiconductor device of claim 10, wherein etching the first layer comprises using a plasma etch.

14. The semiconductor device of claim 10, wherein the at least one support feature comprises a first support feature disposed adjacent to a first side of the outside of the corner feature and a second support feature disposed adjacent to a second side of the outside of the corner feature.

15. A semiconductor device compromising:
a first layer; and
a patterned mask layer on the first layer, wherein the patterned mask layer defines a corner structure, and
wherein the patterned mask layer defines at least one support structure disposed adjacent to an outside of the corner structure.

16. The semiconductor device of claim 15, wherein the patterned mask comprises an acrylic polymer.

17. The semiconductor device of claim 15, wherein the at least one support structure has a width equal to or greater than the line width of the corner feature.

18. The semiconductor device of claim 15, wherein the at least one support structure comprises a first support structure disposed adjacent to a first side of the outside of the corner structure and a second support structure disposed adjacent to a second side of the outside of the corner structure.

19. The semiconductor device of claim 15, further comprising a patterned first layer, wherein the patterned first layer comprises a support structure disposed adjacent to an outside of a corner.

20. The semiconductor device of claim C, wherein the corner structure has an angle of less than 180 degrees.
